(19) United States
(12) Patent Application Publication
(10) Pub. No.: US 2026/0062790 A1
(43) Pub. Date: Mar. 5, 2026

(54) MASK SHEET SUPPORT DEVICE, MASK MANUFACTURING DEVICE, AND METHOD OF MANUFACTURING A MASK

(71) Applicant: Samsung Display Co., Ltd., Yongin-Si (KR)

(72) Inventors: KYONGHO HONG, Yongin-si (KR); Seokho KANG, Yongin-si (KR); WANSUB KIM, Yongin-si (KR); WONYOUNG JANG, Yongin-si (KR); DAUN JO, Yongin-si (KR); SEUNGJU HONG, Yongin-si (KR)

(21) Appl. No.: 19/296,962

(22) Filed: Aug. 12, 2025

(30) Foreign Application Priority Data
Sep. 5, 2024 (KR) 10-2024-0120765
Mar. 20, 2025 (KR) 10-2025-0035949

(51) Int. Cl. C23C 14/04; C23C 14/34; H10K 71/16

(52) U.S. Cl. CPC C23C 14/042; C23C 14/34; H10K 71/166

(57) ABSTRACT

A mask sheet support device is disclosed that includes a support plate and a plurality of clamps. The support plate is configured to support a plurality of mask sheets. The support plate includes a body portion and a damage preventing plate disposed on one surface of the body portion. The plurality of clamps are configured to clamp the plurality of mask sheets. The plurality of clamps are spaced apart from the support plate and disposed along edges of the support plate.

### CROSS-REFERENCE TO RELATED APPLICATION

This application claims priority to and the benefit of Korean Patent Application No. 10-2024-0120765 filed in the Korean Intellectual Property Office on Sep. 5, 2024, and Korean Patent Application No. 10-2025-0035949 filed in the Korean Intellectual Property Office on Mar. 20, 2025, the entire contents of which are incorporated herein by reference.

### BACKGROUND

### 1. Field

The present disclosure relates to a mask sheet support device, a mask manufacturing device, and a method of manufacturing a mask.

### 2. Description of the Related Art

In manufacturing a display device, a metal mask for deposition may be utilized. Metal masks, such as fine metal masks and open masks, may be used in a deposition process to form light emitting layers, electrode layers, and the like on a substrate.

### SUMMARY

The present disclosure provides a mask sheet support device, a mask manufacturing device, and a method of manufacturing a mask that facilitate joining of mask sheets.

An embodiment of a mask sheet support device includes: a support plate configured to support a plurality of mask sheets, the support plate including a body portion and a damage preventing plate disposed on one surface of the body portion; and a plurality of clamps configured to clamp the plurality of mask sheets, the plurality of clamps are spaced apart from the support plate and disposed along edges of the support plate.

The damage preventing plate may be detachable.

The one surface of the support plate may be flat.

The damage preventing plate may include glass or aluminum.

The mask sheet support device may further include a driver coupled to the support plate to move the support plate in a direction perpendicular to the one surface.

At least some of the plurality of clamps may be movable in a direction perpendicular to the one surface of the support plate.

The body portion has a recessed portion on the one surface, and the damage preventing plate may be engaged with the recessed portion.

The damage preventing plate may include a first partial plate, a second partial plate, and a third partial plate spaced apart from each other.

The support plate may have a length extending along a first direction and a width extending along a second direction intersecting the first direction, and when there are defined two imaginary trisecting lines that divide a total area of the support plate into three equal parts along the first direction and each extend in the second direction, and three imaginary 4-dividing lines that divide the total area of the support plate into four equal parts along the first direction and each extend in the second direction, the damage preventing plate has a region including the trisecting lines and the 4-dividing lines.

An embodiment of a mask manufacturing device utilized for joining a plurality of mask sheets to a mask frame includes: a support plate configured to support the plurality of mask sheets, the support plate including a body portion and a damage preventing plate disposed on one surface of the body portion, a plurality of clamps configured to clamp the plurality of mask sheets, the plurality of clamps are spaced apart from the support plate and disposed along edges of the support plate; and a mask stage configured to support the mask frame, the mask stage is positioned on a periphery of the support plate allowing the mask frame to be placed thereon.

The one surface of the support plate may be flat.

The damage preventing plate may include glass or aluminum.

The mask sheet support device may further include a driver coupled to the support plate to move the support plate in a direction perpendicular to the one surface.

At least some of the plurality of clamps may be movable in a direction perpendicular to the one surface of the support plate.

The body portion has a recessed portion on the one surface, and the damage preventing plate may be engaged with the recessed portion.

The damage preventing plate may include a first partial plate, a second partial plate, and a third partial plate spaced apart from each other.

The support plate may have a length extending along a first direction and a width extending along a second direction intersecting the first direction, and when there are defined two imaginary trisecting lines that divide a total area of the support plate into three equal parts along the first direction and each extend in the second direction, and three imaginary 4-dividing lines that divide the total area of the support plate into four equal parts along the first direction and each extend in the second direction, the damage preventing plate has a region including the trisecting lines and the 4-dividing lines.

An embodiment of a method of manufacturing a mask includes: preparing a mask manufacturing device including a support plate, a plurality of clamps, and a mask stage; clamping and pulling the plurality of mask sheets with the plurality of clamps; supporting the plurality of mask sheets by placing the plurality of mask sheets on one surface of the support plate; joining the plurality of mask sheets to each other; and joining the plurality of mask sheets to a mask frame placed on the mask stage, wherein the support plate includes a damage preventing plate on the one surface, and the supporting of the plurality of mask sheets by placing the plurality of mask sheets on one surface of the support plate includes placing a first junction portion in which the plurality of mask sheets is in contact with each other on the one surface of the damage preventing plate.

The method may further include replacing the damage preventing plate.

The support plate may include a removable damage preventing plate on the one surface, and the supporting of the plurality of mask sheets by placing the plurality of mask sheets on one surface of the support plate may include placing a junction portion in which the plurality of mask sheets is in contact with each other on the one surface of the damage preventing plate.

The method may further include adjusting sagging of said plurality of mask sheets by moving said support plate in a direction perpendicular to said one surface.

The method may further include adjusting sagging of said plurality of mask sheets by moving at least some of said plurality of clamps in a direction perpendicular to said one surface.

According to embodiments of the present disclosure, the divided mask sheets may be easily joined together.

### BRIEF DESCRIPTION OF THE DRAWINGS

FIG. 1 is a diagram illustrating a process for performing deposition by using a metal mask.

FIG. 2 is a diagram illustrating divided sheets used in a metal mask.

FIG. 3 is a cross-sectional view of the divided sheet cut along line III-III′ of FIG. 2.

FIG. 4 is a diagram illustrating a mask manufacturing device according to an embodiment.

FIG. 5 is a schematic cross-sectional view of the mask manufacturing device according to an embodiment, cut along line V-V′ of FIG. 4.

FIG. 6 is a diagram illustrating the mask manufacturing device and a divided sheet according to an embodiment.

FIG. 7 is a schematic cross-sectional view of the mask manufacturing device according to an embodiment cut along line VII-VII′ in FIG. 6.

FIG. 8 is a diagram illustrating a method of adjusting sagging of the mask sheet by the mask manufacturing device according to an embodiment.

FIG. 9 is an enlarged view of region IX of FIG. 5.

FIG. 10 is a diagram illustrating an imaginary trisecting line that trisects a support plate.

FIG. 11 is a diagram illustrating an imaginary 4-dividing line that quarters the support plate.

FIG. 12 is a flowchart illustrating a method of manufacturing a mask according to an embodiment.

### DETAILED DESCRIPTION

Hereinafter, with reference to the accompanying drawings, various embodiments of the present disclosure will be described in detail such that a person skilled in the art to which the disclosure pertains can easily implement the embodiments. The present disclosure may be variously implemented and is not limited to the following embodiments.

In order to clearly describe the present disclosure, parts unrelated to the explanation have been omitted, and, throughout the entire specification, the same reference numerals are designated for the same or similar elements.

In addition, the size and thickness of each configuration illustrated in the drawings are arbitrarily illustrated for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it may be directly on the other element or intervening elements may also be present. In contrast, when an element is referred to as being “directly on” another element, there are no intervening elements present. Further, it will be understood that when an element such as a layer, film, region, or substrate is referred to as being “above” or “on” a reference part, it means that it may be disposed either above or below the reference part, and it does not necessarily mean being positioned “above” or “on” in the direction opposite to gravity.

In addition, unless explicitly described to the contrary, the words “comprise” and “include” as well as variations such as “comprises” and “comprising,” will be understood to imply the inclusion of stated elements but not the exclusion of any other elements.

Further, in the entire specification, when it is referred to as “in a plan view” it means when a target part is viewed from above, and when it is referred to as “in a cross-sectional view”, it means when the cross-section obtained by cutting a target part vertically is viewed from the side.

In manufacturing a display device, a metal mask for deposition may be utilized. Metal masks, such as fine metal masks and open masks, may be used in a deposition process to form light emitting layers, electrode layers, and the like on a substrate.

In order to produce more display devices in a single process, the substrates used to manufacture display devices are increasing in size. As the substrates become larger, the metal masks that deposit the deposition material on the substrates need to be larger as well. The metal mask may be manufactured by joining a mask sheet to a mask frame. Therefore, large mask frames and large mask sheets may be required to manufacture large metal masks.

Manufacturing large mask sheets may be expensive. Therefore, it may be cost advantageous to manufacture a single mask sheet by joining a plurality of divided sheets. The divided sheets may be small mask sheets. Two or more divided sheets may be joined together to form a single large mask sheet.

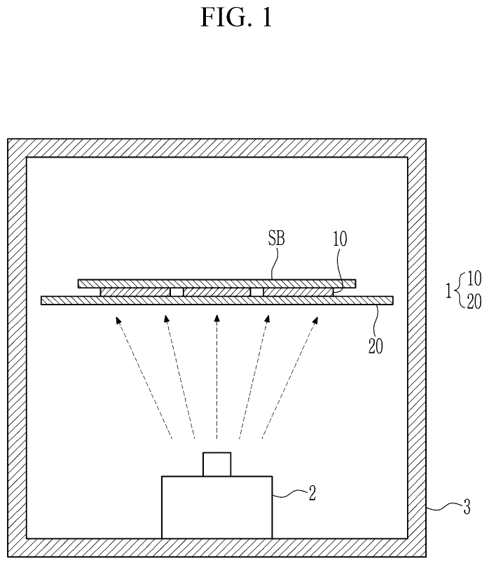

FIG. 1 is a diagram illustrating a process for performing deposition by using a metal mask.

FIG. 1 illustrates a metal mask 1, a substrate SB, a deposition source 2, and a chamber 3. The metal mask 1 may include a mask sheet 10 and a mask frame 20.

When sputtering in the chamber 3, particles ejected from the deposition source 2 pass through the metal mask 1 and are deposited on the substrate SB to form a thin film with a predetermined pattern. Specifically, when the substrate SB and the metal mask 1 are positioned inside the chamber 3, the deposition source 2 may supply deposition material to deposit the deposition material on the substrate SB. This deposition material may form at least one of various layers stacked on the substrate SB. For example, the deposition material may form one of a hole transport layer, a hole injection layer, an emission layer, an electron transport layer, or an electron injection layer.

By using a high-precision metal mask 1, the deposition material can be precisely deposited on the substrate SB. The precision of the metal mask 1 can be improved by forming the mask sheet 10 into a flat shape.

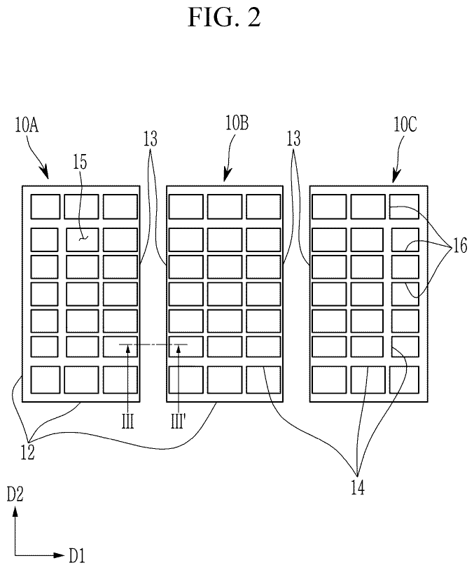

FIG. 2 is a diagram illustrating divided sheets used in the metal mask.

FIG. 2 illustrates a first divided sheet 10A, a second divided sheet 10B, and a third divided sheet 10C. The first divided sheet 10A, the second divided sheet 10B, and the third divided sheet 10C may be joined together to form a single large mask sheet 10. That is, the first divided sheet 10A, the second divided sheet 10B, and the third divided sheet 10C may form portions of the large mask sheet 10. The size of the large mask sheet 10 formed by joining the first divided sheet 10A, the second divided sheet 10B, and the third divided sheet 10C may be approximately the same as the size of the substrate. The first divided sheet 10A, the second divided sheet 10B, and the third divided sheet 10C may be joined in the state where the first divided sheet 10A, the second divided sheet 10B, and the third divided sheet 10C are arranged in sequence along a first direction D1.

The divided sheets 10A, 10B, and 10C may be made of a metal having a certain degree or greater of rigidity and a low coefficient of thermal expansion. For example, the divided sheets 10A, 10B, and 10C may include any one of stainless steel (SUS), Invar alloys, nickel (Ni), cobalt (Co), nickel alloys, and nickel-cobalt alloys.

Each of the divided sheets 10A, 10B, and 10C may include a clamping portion 12, a first junction portion 13, a second junction portion 14, and an opening 15.

The clamping portion 12 may be disposed at the outermost part of the divided sheets 10A, 10B, and 10C. The clamping portion 12 may be clamped by a clamp of a mask manufacturing device, and the clamp can pull the divided sheets 10A, 10B, and 10C tightly by clamping the clamping portion 12.

The divided sheets 10A, 10B, and 10C may have the first junction portion 13 on at least one side. The first junction portion 13 may refer to one side where adjacent divided sheets are joined to each other.

The first junction portion 13 located on one side of the first divided sheet 10A may be joined with the first junction portion 13 located on one side of the second divided sheet 10B. The first junction portion 13 located on the other side opposite the one side of the second divided sheet 10B may be joined with the first junction portion 13 located on one side of the third divided sheet 10C. The method of joining the divided sheets at the first junction portion 13 is not limited. For example, the divided sheets may be joined by laser welding. Joining the divided sheets 10A, 10B, and 10C may complete the single mask sheet 10.

The divided sheets 10A, 10B, and 10C may have the second junction portion 14 on at least one side. The second junction portion 14 may be located on a side where the first junction portion 13 is not located. The second junction portion 14 of the divided sheets 10A, 10B, and 10C may be located overlapping one edge of the divided sheets 10A, 10B, and 10C where the clamping portion 12 is located. The second junction portion 14 of the divided sheets 10A, 10B, and 10C may be positioned on the inner side of the clamping portion 12. For example, the first divided sheet 10A has the first junction portion 13 on one side and three second junction portions 14 on three sides where the first junction portion 13 is not disposed. The second divided sheet 10B has the first junction portion 13 on two sides and has the second junction portion 14 on two sides where the first junction portion 13 is not disposed. The third divided sheet 10C has the first junction portion 13 on one side and the second junction portion 14 on three sides where the first junction portion 13 is not disposed. The divided sheets 10A, 10B, and 10C may be joined to the mask frame through the second junction portion 14.

A single large mask sheet manufactured by connecting the divided sheets 10A, 10B, and 10C together may be joined to a mask frame to produce a metal mask. The large mask sheet and the mask frame may be joined by the second junction portion 14. The second junction portion 14 of the divided sheets 10A, 10B, and 10C when connected may form substantially the same shape and size as the mask frame. The second junction portion 14 may be located on the inner side of the clamping portion 12 and may be located along the outer portion of the mask sheet 10. For example, the large mask sheet 10 manufactured by joining the divided sheets 10A, 10B, and 10C of FIG. 2 may be joined to a mask frame having a square shape. The second junction portion 14 of the divided sheets 10A, 10B, and 10C of FIG. 2 may be disposed along a square picture frame shape.

The mask sheet 10 may include the opening 15. Deposition material passing through the openings 15 may be deposited on the substrate to form a thin film. The shape of the opening 15 may vary depending on the shape of the display device. The number of openings 15 may vary depending on the size of the substrate or the size of the display device. Since the shape and size of the opening 15 are determined by the size of the display device, the width of the material surrounding the openings 15 may be determined as needed. For example, the width of the material defining the openings 15 of the divided sheets 10A, 10B, and 10C may be wider or narrower depending on their locations. The mask sheet 10 may include a plurality of openings 15.

FIG. 2 shows that the clamping portion 12 and the second junction portion 14 are connected by a plurality of connection portions 16. The shape and number of the plurality of connection portions 16 are not limited.

FIG. 2 shows three divided sheets 10A, 10B, and 10C that form a large mask sheet. However, the large mask sheet may also be formed by joining two divided sheets or four or more divided sheets.

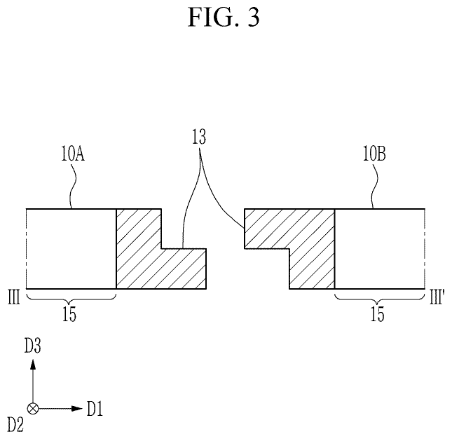

FIG. 3 is a cross-sectional view of the divided sheet cut along line III-III′ of FIG. 2.

FIG. 3 is a diagram illustrating a method of joining the first divided sheet 10A and the second divided sheet 10B. Specifically, the first junction portions 13 of the first divided sheet 10A and the second divided sheet 10B are described. FIG. 3 illustrates a method of joining the first divided sheet 10A and the second divided sheet 10B, but the method may be applied to any joining between divided sheets.

The divided sheet has the opening 15, and the opening 15 may be formed by an etching process. The etching process may be a method of selectively removing a material to form a pattern of openings in the mask sheet. For example, wet etching or dry etching may be utilized to form the opening 15. Wet etching may be a method of removing a specific portion of the material by using a chemical solution. Dry etching may be a method of removing a material by using plasma or reactive gas. The etching process may remove the material in an area corresponding to the opening 15 to form the opening 15.

An etching process may be performed on a portion of the first junction portion 13 of each of the first divided sheet 10A and the second divided sheet 10B to form a step. For example, the first junction portion 13 may include a stair-shaped step. The first junction portion 13 of each of the first divided sheet 10A and the second divided sheet 10B may be interlocked with each other and laser welded. Thereby, the large mask sheet can be manufactured while minimizing protrusion in the thickness direction.

Specifically, the step of the first junction portion 13 may be formed by performing a half-etching process that removes only half of the material without penetrating through the material of the divided sheet. If the first divided sheet 10A and the second divided sheet 10B are joined without performing the half-etching process, the surface of the mask sheet may not be flat. By making the surface of the mask sheet flat, the reliability of the metal mask can be improved. At the first junction portion 13 of the first divided sheet 10A, the half-etching process may be performed in the direction from top to bottom, and at the first junction portion 13 of the second divided sheet 10B, the half-etching process may be performed in the direction from bottom to top. That is, at the first junction portion 13 of the first divided sheet 10A, the half-etching process may be performed in the opposite direction of the third direction D3, and at the first junction portion 13 of the second divided sheet 10B, the half-etching process may be performed in the third direction D3. The third direction D3 may be a direction perpendicular to each of the first direction D1 and the second direction D2. Thereby, at the first junction portion 13 of the first divided sheet 10A, an upper portion of the material may be removed, and at the first junction portion 13 of the second divided sheet 10B, a lower portion of the material may be removed.

A flat surface may be formed by connecting the first junction portion 13 of the first divided sheet 10A and the first junction portion 13 of the second divided sheet 10B where the half-etching process has been performed. The first junction portion 13 of the first divided sheet 10A and the first junction portion 13 of the second divided sheet 10B may be shaped to interlock with each other. The connected first divided sheet 10A and second divided sheet 10B may be joined by a predetermined process. For example, the first junction portion 13 of the first divided sheet 10A and the first junction portion 13 of the second divided sheet 10B may be joined by laser welding.

Furthermore, FIG. 3 illustrates the shape in which the first junction portion 13 of the first divided sheet 10A has a recessed portion recessed from the top and the first junction portion 13 of the second divided sheet 10B has a recessed portion recessed from the bottom, but the first junction portion 13 of the first divided sheet 10A may have a recessed portion recessed from a bottom and the first junction portion 13 of the second divided sheet 10B may have a recessed portion recessed from a top portion.

In order for the divided sheet to be properly joined to the divided sheet, it is necessary for the divided sheets to be joined in a flat and unrolled state. The divided sheets may be fastened by the clamp to be pulled tight, but the fastening by the clamp alone may cause the middle of the divided sheet to be sagged by the weight of the divided sheet. A metal mask with an uneven surface may not have excellent precision. Furthermore, a display device manufactured by using the metal mask with the uneven surface may be defective. In the joining between the divided sheets, a metal mask with a flat surface may be manufactured by preventing the divided sheets from being sagged by the weight of the divided sheet.

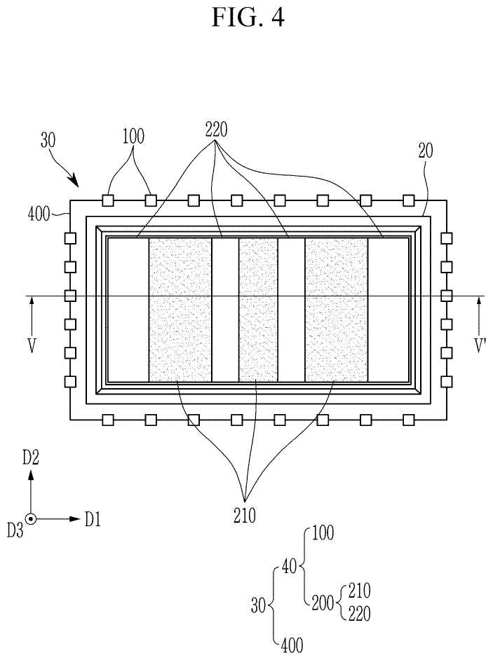

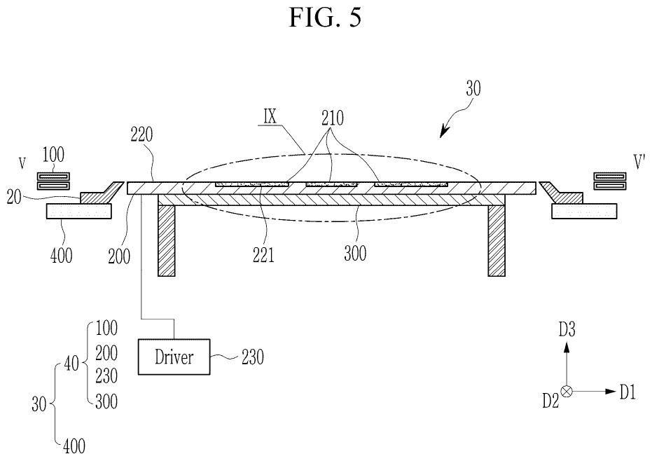

Hereinafter, a mask manufacturing device according to an embodiment will be described in detail with reference to FIGS. 4 and 5. FIG. 4 is a diagram illustrating a mask manufacturing device according to an embodiment. FIG. 5 is a schematic cross-sectional view of the mask manufacturing device according to the embodiment cut along line V-V′ of FIG. 4.

FIG. 5 shows cross-sections of a support plate 200, a clamp 100, a mask stage 400, a mask frame 20, and a support part 300. FIG. 5 also illustrates a driver 230 coupled and connected to the support plate 200.

A mask manufacturing device 30 may include a mask sheet support device 40 and the mask stage 400. The mask sheet support device 40 may include the clamp 100 and the support plate 200. The support plate 200 may include a damage preventing plate 210 and the body portion 220.

A plurality of divided sheets may be placed on one surface of the support plate 200. One surface of the support plate may be flat. Because the one surface of the support plate 200 on which the plurality of divided sheets are disposed is flat, the support plate 200 may support the plurality of divided sheets to be joined to each other to have a flat shape. The support plate 200 may be a rectangular plate. The size of the support plate 200 may be substantially the same as the size of the substrate.

The clamps 100 are spaced apart from the support plate 200 and disposed along edges of the support plate 200, and may be configured to clamp a plurality of mask sheets. The clamps 100 may be provided in a plurality. The plurality of clamps 100 may be spaced apart from the support plate 200 in a first direction D1 and a second direction D2. Further, the plurality of clamps 100 may be spaced apart from the support plate 200 in the third direction D3. The plurality of clamps 100 may surround the support plate 200 at regular intervals. The number and shape of the clamps 100 are not limited. The support plate 200 having a larger area may require a greater number of clamps 100 than the support plate 200 having a smaller area. The clamps 100 may clamp the clamping portion 12 of the mask sheet. The plurality of clamps 100 may be freely movable in the first direction D1 and the second direction D2 which are planar directions of one surface of the support plate 200. The clamps 100 may clamp the clamping portion of the divided sheet and move to transport the divided sheet. Further, the clamp 100 may pull the divided sheet tight.

The damage preventing plate 210 may be a portion of the support plate 200. One surface of the damage preventing plate 210 may form a part of one surface of the support plate 200. For example, the damage preventing plate 210 may be defined as a part of the upper portion of the support plate 200. The damage preventing plate 210 may be removable from one surface of the support plate 200 and can be replaced with a new one. The damage preventing plate 210 may include a material that is resistant to laser damage. For example, the damage preventing plate 210 may include glass or aluminum.

The body portion 220 may be a portion of the support plate 200. The body portion 220 may support the damage preventing plate 210. For example, the body portion 220 may be defined as a part of a lower portion and a part of an upper portion of the support plate 200. The body portion 220 may include a recessed portion 221 on one surface to accommodate the damage preventing plate 210. The damage preventing plate 210 may be inserted into the recessed portion 221 of the body portion 220 to be coupled with the body portion 220. As the damage preventing plate 210 is inserted into the recessed portion 221 of the body portion 220, one surface of the support plate 200 may be flat. The recessed portion 221 of the body portion 220 may be provided in a plurality.

The mask stage 400 may be located on the periphery of the support plate 200 and the mask frame 20 may be placed on the mask stage 400 and supported by the mask stage 400. The mask stage 400 and the mask sheet support device 40 may form the mask manufacturing device 30. The mask manufacturing device 30 may enable quickly manufacturing a metal mask by forming a large mask sheet by joining a plurality of divided sheets to the mask frame 20. The mask stage 400 may be spaced apart from the support plate 200 in the first direction D1 and the second direction D2.

The driver 230 may be coupled to the support plate 200 to move the support plate 200 in the direction perpendicular to one surface on which the divided sheet is placed. The support plate 200 may move along the third direction D3. The driver 230 may raise or lower the support plate 200. The driver 230 has no limitations on the method of raising or lowering the support plate 200. For example, the driver 230 can raise or lower only the support plate 200. Alternatively, the driver 230 can raise or lower the support plate 200 by adjusting the length of the support part 300. Also, There are no limitations on the driving method of the driver 230. For example, the driver 230 may be a motor or a pneumatic cylinder.

The support part 300 may support the support plate 200. The support part 300 is fixed to the ground and may adjust the position of the clamp 100 and the support plate 200. The support part 300 may be fixed to prevent the support plate 200 from wobbling.

The mask sheet support device 40 according to an embodiment of the present disclosure may prevent sagging of the mask sheet. Further, the mask manufacturing device 30 according to an embodiment may be utilized to join a plurality of mask sheets 10 to the mask frame 20.

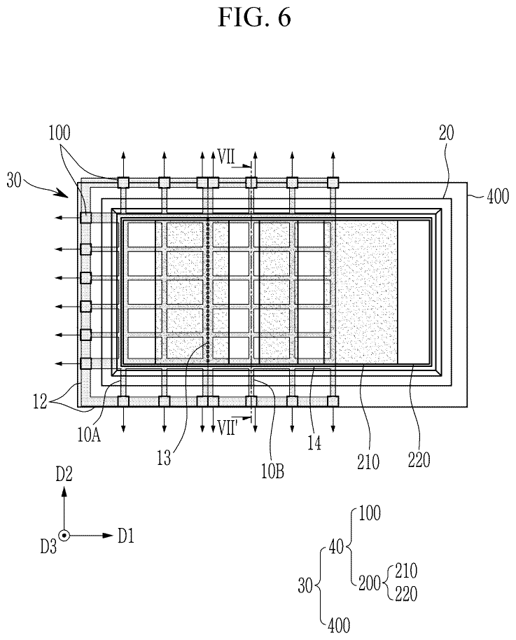

Hereinafter, with reference to FIGS. 6 to 8, the process of placing and bonding the first divided sheet and the second divided sheet on the support plate of the mask manufacturing device will be examined in detail.

FIG. 6 is a diagram illustrating the mask manufacturing device and a divided sheet according to an embodiment.

FIG. 6 illustrates the first divided sheet 10A and the second divided sheet 10B placed on the mask manufacturing device 30.

The first divided sheet 10A and the second divided sheet 10B may be clamped and pulled tight by the clamp 100. Further, the first divided sheet 10A and the second divided sheet 10B may be joined at one surface of the support plate 200.

The first divided sheet 10A and the second divided sheet 10B may be clamped and pulled tight by the plurality of clamps 100. The first divided sheet 10A and the second divided sheet 10B may include the plurality of clamping portions 12. The clamping portions 12 may be positioned at the outermost portions of the divided sheets 10A and 10B. The clamps 100 can pull the divided sheets 10A and 10B toward the outer edges of the divided sheets 10A and 10B. Thereby, the positions of the first divided sheet 10A and the second divided sheet 10B can be maintained. Further, force may be applied to flatten the first divided sheet 10A and the second divided sheet 10B in a direction perpendicular to the direction of gravity.

The first divided sheet 10A and the second divided sheet 10B are made of a very thin metal which may be easily bent even with small force. Thus, even if the clamps 100 pull the clamping portions 12 at the outermost parts of the divided sheets 10A and 10B, the divided sheets 10A and 10B may sag in the gravitational direction due to their own weight. To prevent this, placing the divided sheets 10A and 10B on the support plate 200 can prevent sagging in the gravitational direction.

Since one surface of the support plate 200 on which the divided sheets 10A and 10B are placed is flat, when the divided sheets 10A and 10B are placed on the support plate 200, the first junction portion 13 where the divided sheets 10A and 10B are joined to each other may have good flatness. Since the divided sheets 10A and 10B are joined to each other with good flatness at the first junction portion 13, the metal mask formed using the mask manufacturing device 30 according to an embodiment may have good precision.

The first junction portion 13, where the divided sheets 10A and 10B are joined, may be placed on the damage preventing plate 210. The damage preventing plate 210 may be more resistant to lasers compared to the body portion 220. That is, the damage preventing plate 210 may be less susceptible to laser damage compared to the body portion 220. Thus, by placing the first junction portion 13 of the divided sheets 10A and 10B on the damage preventing plate 210 rather than the body portion 220, the lifespan of the support plate 200 may be extended. Furthermore, since the damage preventing plate 210 is removable from the support plate 200 and can be replaced with a new one, the damage preventing plate 210 damaged by repeated laser irradiation can be easily replaced. The damage preventing plate 210 is removable from the recessed portion 221 in the body portion 220, so that the damage preventing plate 210 may be easily replaced. Since the damage preventing plate 210 is located in a recessed portion 221 of the body portion 220, one surface of the support plate 200 may be kept flat.

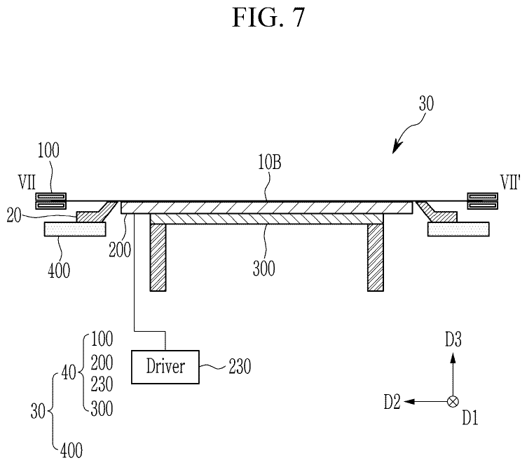

FIG. 7 is a schematic cross-sectional view of the mask manufacturing device according to an embodiment cut along line VII-VII′ in FIG. 6.

Two clamps 100 facing each other can pull the second divided sheet 10B in opposite directions along the second direction D2. The second divided sheet 10B may be placed on the body portion 220 of the support plate 200. The second divided sheet 10B is supported by the support plate 200 so that the second divided sheet 10B may remain flat in the first direction D1 and the second direction D2.

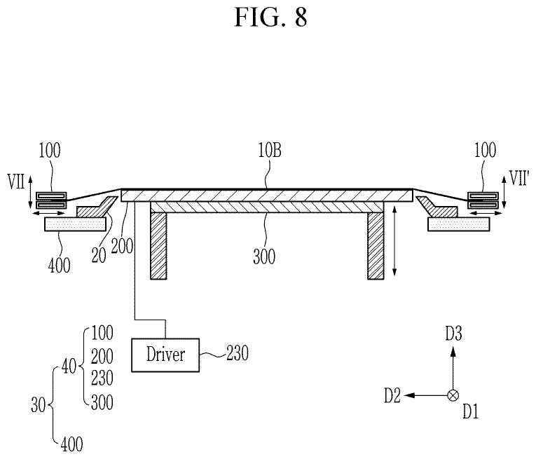

FIG. 8 is a diagram illustrating a method of adjusting sagging of the mask sheet by the mask manufacturing device according to an embodiment.

The second divided sheet 10B may be clamped by the clamp 100 and pulled tight. Further, the second divided sheet 10B is placed on the support plate 200 and supported so that the second divided sheet 10B may maintain a flat shape. However, it may be necessary to further flatten the second divided sheet 10B. To this end, the clamps 100 clamping the second divided sheet 10B may be moved in a downward direction. That is, the clamp 100 may be moved in the opposite direction of the third direction D3. In other words, the clamps 100 may be moved in the gravitational direction. As a result, the second divided sheet 10B may be more strongly in close contact with the support plate 200 to be pulled tight.

At least some of the plurality of clamps 100 are movable in a direction perpendicular to one surface of the support plate 200. By moving only some of the plurality of clamps (100), the mask sheet can be finely adjusted.

Furthermore, the support plate 200 supporting the second divided sheet 10B may be moved in the direction opposite to gravity. That is, the support plate 200 may be moved in the third direction D3. By raising the support plate 200 in the third direction D3, the second divided sheet 10B may be more tightly adhered to the support plate 200 and pulled taut.

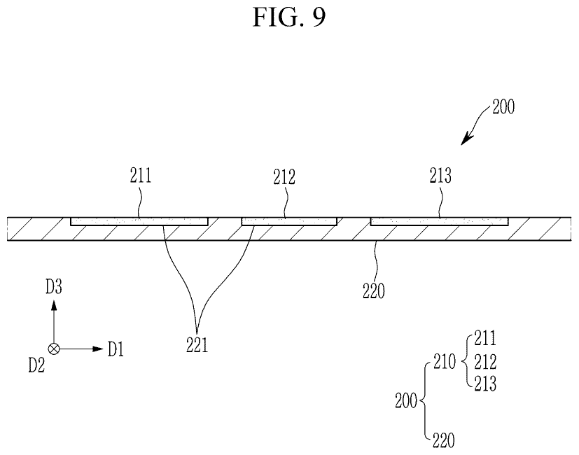

Hereinafter, the support plate including the damage preventing plate and the body portion will be described in detail with reference to FIGS. 9 to 11.

FIG. 9 is an enlarged view of region IX of FIG. 5.

FIG. 9 illustrates the support plate 200 including the damage preventing plate 210 and the body portion 220.

The damage preventing plate 210 in FIG. 9 may include a first partial plate 211, a second partial plate 212, and a third partial plate 213. The body portion 220 may include three recessed portions 221 extending in the second direction D2 and arranged spaced apart along the first direction D1. One surface of the body portion 220 including the three recessed portions 221 illustrated in FIG. 9 may have an uneven surface shape. The first partial plate 211, the second partial plate 212, and the third partial plate 213 may be fitted into the three recessed portions 221, respectively. The sizes of the first partial plate 211, the second partial plate 212, and the third partial plate 213 may be the same as each other or may be different from each other. The first partial plate 211, the second partial plate 212, and the third partial plate 213 may be arranged at the same intervals or different intervals along the first direction D1.

FIG. 9 illustrates a shape in which each of the first partial plate 211, the second partial plate 212, and the third partial plate 213 are spaced apart in the recessed portion 221. FIG. 9 also illustrates the recessed portion 221 having right-angled edges. FIG. 9 also illustrates that each of the first partial plate 211, the second partial plate 212, and the third partial plate 213 has a cuboidal shape. However, in other examples, the recessed portions may have curved corners. Furthermore, in other examples, each of the first partial plate 211, the second partial plate 212, and the third partial plate 213 may not have a cuboidal shape.

One surface of the damage preventing plate 210 on which the divided sheets are placed may have a flat shape. Furthermore, the shapes of the first partial plate 211, the second partial plate 212, and the third partial plate 213 may correspond to the shape of the recessed portions 221. As a result, the damage preventing plate 210 may be easily attached to and detached from the body portion 220.

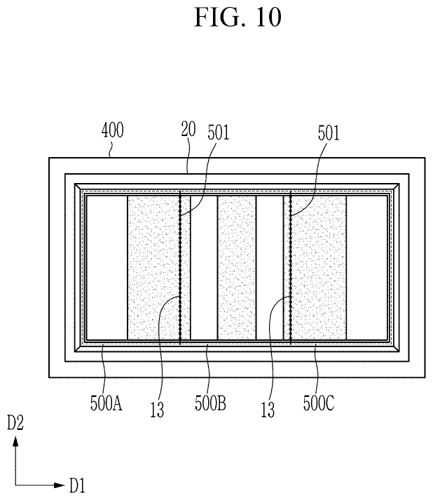

FIG. 10 is a diagram illustrating imaginary trisecting lines that trisect a support plate.

The support plate 200 may have a length and a width extending along the first direction D1 and the second direction D2, respectively, which intersect each other.

The imaginary trisecting lines 501 may trisect a region of the support plate 200 along the first direction D1. The trisected support plate 200 may include a first divided region 500A, a second divided region 500B, and a third divided region 500C. One divided sheet may be placed on each of the divided regions. The first junction portion 13 where adjacent divided sheets are joined may overlap the trisecting lines 501. Furthermore, the trisecting lines 501 may be positioned while overlapping the damage preventing plate 210. Additionally, the first junction portion 13 may be positioned to overlap with the damage preventing plate 210.

The trisecting lines 501 may be positioned freely along the first direction. Thus, the areas of the first divided region 500A, the second divided region 500B, and the third divided region 500C may be the same or different.

For example, when two imaginary trisecting lines are defined that trisect the entire area of the support plate 200 along the first direction D1 and extend each in the second direction D2, the damage preventing plate 210 may have an area that includes both trisecting lines 501.

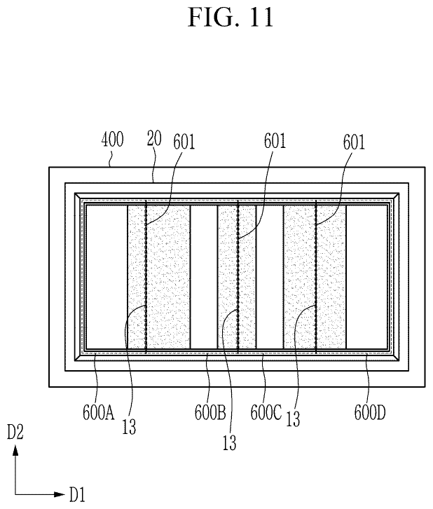

FIG. 11 is a diagram illustrating imaginary dividing lines that divide the support plate into four divided regions.

An imaginary dividing lines 601 may divide a region of the support plate 200 along the first direction D1. The divided support plate 200 may be a first divided region 600A, a second divided region 600B, a third divided region 600C, and a fourth divided region 600D. One divided sheet may be placed on each of the divided regions. The first junction portion 13 where adjacent divided sheets are joined may overlap the dividing line 601. Furthermore, the dividing line 601 may be positioned while overlapping the damage preventing plate 210. Also, the first junction portion 13 may be positioned to overlap with the damage preventing plate 210.

The dividing line 601 may be freely formed along the first direction. Thus, the areas of the first divided region 600A, the second divided region 600B, the third divided region 600C, and the fourth divided region 600D may be the same or different.

For example, when three imaginary dividing lines are defined that divide the entire area of the support plate 200 along the first direction D1 and extend each in the second direction D2, the damage preventing plate 210 may have an area that includes all of the dividing lines 601.

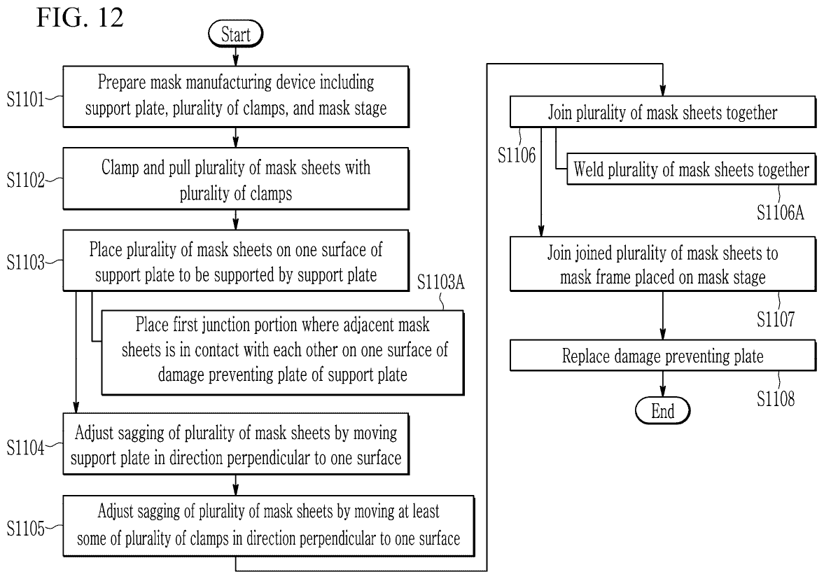

FIG. 12 is a flowchart illustrating a method of manufacturing a mask according to an embodiment.

First, a mask manufacturing device including a support plate, a plurality of clamps, and a mask stage is prepared (S1101). The support plate may include a damage preventing plate located in a recessed portion of a body portion. The damage preventing plate may be easily replaced in case the damage preventing plate is damaged. The damage preventing plate may be detachable from the recessed portion of the body portion.

When the mask manufacturing device is ready, the plurality of mask sheets are clamped and pulled with a plurality of clamps (S1102). The plurality of mask sheets may be in a state of being clamped by the clamps and positioned on the support plate. The clamps may pull the mask sheets in a direction perpendicular to the gravitational direction.

Subsequently, the plurality of mask sheets is placed on one surface of the support plate to be supported by the support plate (S1103). Since the one surface of the support plate has a flat shape, by placing the mask sheets on the one surface of the support plate, the mask sheets may be supported by the support plate in a flat shape. Operation S1103 in which the plurality of mask sheets is placed on one surface of the support plate may include operation S1103A of placing a first junction portion where the adjacent mask sheets is in contact with each other on the one surface of the damage preventing plate of the support plate.

Next, the sagging of the plurality of mask sheets is adjusted by moving the support plate in a direction perpendicular to its one surface (S1104). The support plate may be raised or lowered in the gravitational direction by the driver. The gravitational direction may be a direction perpendicular to one surface of the support plate.

Subsequently, the sagging of the plurality of mask sheets is adjusted by moving at least one of the plurality of clamps in the direction perpendicular to the one surface (S1105). By moving only some of the clamps in the direction perpendicular to the one surface, the sagging of the mask sheets may be precisely adjusted. For example, if the support plate has an inclination, the sagging of the mask sheets may be easily adjusted by moving only some of the opposing clamps. The step of adjusting the sagging of the plurality of mask sheets by moving at least some of the plurality of clamps in a direction perpendicular to the one surface may be omitted. Additionally, either Operation S1104, in which the sagging of the plurality of mask sheets is adjusted by moving the support plate in a direction perpendicular to the one surface, or Operation S1105, in which the sagging of the plurality of mask sheets is adjusted by moving at least one of the plurality of clamps in the direction perpendicular to the one surface, may be performed, but not both.

After the sagging of the mask sheets have been adjusted, the plurality of mask sheets is joined together (S1106). The plurality of mask sheets may be different divided sheets. The plurality of mask sheets may be joined together to form a single large mask sheet. The operation of joining the plurality of mask sheets together may include welding the plurality of mask sheets together. (S1106A) That is, the plurality of mask sheets may be joined by welding at the first junction portion.

Next, the plurality of joined mask sheets is joined to a mask frame placed on the mask stage (S1107). The plurality of joined mask sheets may be one large mask sheet formed by joining a plurality of divided sheets to each other.

After the plurality of mask sheets are joined to each other in a state of being pulled taut by the elevation of the support plate, the support plate may be lowered again to join the plurality of joined mask sheets and the mask frame. Accordingly, alignment adjustment may occur between the plurality of joined mask sheets and the mask frame. The plurality of clamps control the force pulling the plurality of joined mask sheets so that alignment between the joined mask sheets and the mask frame can be properly achieved. Subsequently, the plurality of joined mask sheets may be laser welded to the mask frame.

After the plurality of joined mask sheets and the mask frame are joined by laser welding, the clamping portions of the plurality of joined mask sheets may be removed.

The plurality of joined mask sheets may form a single large mask sheet, and a metal mask may be manufactured by joining the large mask sheet to the mask frame. The second junction portion of the large mask sheet and the mask frame may be joined by laser welding.

Then, when the damage preventing plate is severely damaged, the damage preventing plate is removed and replaced with a new one (S1108). Since the damage preventing plate is removable and can be replaced, the support plate of the mask manufacturing device may be used semi-permanently.

In this way, joining between the mask sheets may be facilitated by the mask manufacturing device according to an embodiment including the support plate capable of supporting mask sheets.

Furthermore, the support plate of the mask manufacturing device according to an embodiment may be moved in a direction perpendicular to one surface on which the mask sheet is placed so that the mask sheet may be excellently flattened.

Furthermore, the mask manufacturing device according to an embodiment may include the removable damage preventing plate on the support plate to facilitate replacement of a damaged damage preventing plate. This may extend the lifespan of the mask manufacturing device according to an embodiment.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A mask sheet support device comprising:
a support plate configured to support a plurality of mask sheets, the support plate including a body portion and a damage preventing plate disposed on one surface of the body portion; and
a plurality of clamps configured to clamp the plurality of mask sheets, the plurality of clamps are spaced apart from the support plate and disposed along edges of the support plate.

2. The mask sheet support device of claim 1, wherein:
the damage preventing plate is detachable.

3. The mask sheet support device of claim 1, wherein:
the damage preventing plate includes glass or aluminum.

4. The mask sheet support device of claim 1, further comprising:
a driver coupled to the support plate to move the support plate in a direction perpendicular to the one surface.

5. The mask sheet support device of claim 1, wherein:
at least some of the plurality of clamps is movable in a direction perpendicular to the one surface of the support plate.

6. The mask sheet support device of claim 1, wherein:
the body portion has a recessed portion on the one surface, and
the damage preventing plate is engaged with the recessed portion.

7. The mask sheet support device of claim 6, wherein:
the damage preventing plate includes a first partial plate, a second partial plate, and a third partial plate spaced apart from each other.

8. The mask sheet support device of claim 7, wherein:
the support plate has a length extending along a first direction and a width extending along a second direction intersecting the first direction, and
when there are defined two imaginary trisecting lines that divide a total area of the support plate into three equal parts along the first direction and each extend in the second direction, and three imaginary 4-dividing lines that divide the total area of the support plate into four equal parts along the first direction and each extend in the second direction,
the damage preventing plate has a region including the trisecting lines and the 4-dividing lines.

9. A mask manufacturing device utilized for joining a plurality of mask sheets to a mask frame, the mask manufacturing device comprising:
a support plate configured to support the plurality of mask sheets, the support plate including a body portion and a damage preventing plate disposed on one surface of the body portion,
a plurality of clamps configured to clamp the plurality of mask sheets, the plurality of clamps are spaced apart from the support plate and disposed along edges of the support plate; and
a mask stage configured to support the mask frame, the mask stage is positioned on a periphery of the support plate allowing the mask frame to be placed thereon.

10. The mask manufacturing device of claim 9, wherein:
the damage preventing plate is detachable.

11. The mask manufacturing device of claim 9, wherein:
the damage preventing plate includes glass or aluminum.

12. The mask manufacturing device of claim 9, further comprising:
a driver coupled to the support plate to move the support plate in a direction perpendicular to the one surface.

13. The mask manufacturing device of claim 9, wherein:
at least some of the plurality of clamps is movable in a direction perpendicular to the one surface of the support plate.

14. The mask manufacturing device of claim 9, wherein:
the body portion has a recessed portion on the one surface, and
the damage preventing plate is engaged with the recessed portion.

15. The mask manufacturing device of claim 14, wherein:
the damage preventing plate includes a first partial plate, a second partial plate, and a third partial plate spaced apart from each other.

16. The mask manufacturing device of claim 15, wherein:
the support plate has a length extending along a first direction and a width extending along a second direction intersecting the first direction, and
when there are defined two imaginary trisecting lines that divide a total area of the support plate into three equal parts along the first direction and each extend in the second direction, and three imaginary 4-dividing lines that divide the total area of the support plate into four equal parts along the first direction and each extend in the second direction,
the damage preventing plate has a region including the trisecting lines and the 4-dividing lines.

17. A method of manufacturing a mask comprising:
preparing a mask manufacturing device including a support plate, a plurality of clamps, and a mask stage;
clamping and pulling the plurality of mask sheets with the plurality of clamps;
supporting the plurality of mask sheets by placing the plurality of mask sheets on one surface of the support plate;
joining the plurality of mask sheets to each other; and
joining the plurality of mask sheets to a mask frame placed on the mask stage,
wherein the support plate includes a damage preventing plate on the one surface, and
wherein the supporting of the plurality of mask sheets by placing the plurality of mask sheets on one surface of the support plate includes placing a first junction portion in which the plurality of mask sheets is in contact with each other on the one surface of the damage preventing plate.

18. The method of claim 17, further comprising:
replace the damage preventing plate.

19. The method of claim 17, further comprising:
adjusting sagging of the plurality of mask sheets by moving the support plate in a direction perpendicular to the one surface.

20. The method of claim 17, further comprising:
adjusting sagging of the plurality of mask sheets by moving at least one of the plurality of clamps in a direction perpendicular to the one surface.
